(19) United States
(12) Patent Application Publication
(10) Pub. No.: US 2011/0024837 A1
(43) Pub. Date: Feb. 3, 2011

(54) SEMICONDUCTOR DEVICE AND METHOD FOR FABRICATING THE SAME

(76) Inventor: Kyung-Doo KANG, Gyeonggi-do (KR)

Correspondence Address: IP & T GROUP LLP, 7700 Little River Turnpike, Suite 207, Annandale, VA, 22003, US

(21) Appl. No.: 12/823,566

(22) Filed: Jun. 25, 2010

(30) Foreign Application Priority Data
Jul. 31, 2009 (KR) 10-2009-0070569

(51) Int. Cl. H01L 29/78; H01L 21/336

(52) U.S. Cl. 257/336; 438/294; 438/301; 257/E21.409; 257/E29.256

(57) ABSTRACT

A semiconductor device includes a gate formed over a substrate, a junction region formed in the substrate at both sides of the gate, and a depletion region expansion prevention layer surrounding sidewalls of the junction region in the substrate.

### CROSS-REFERENCE TO RELATED APPLICATIONS

The present application claims priority of Korean Patent Application No. 10-2009-0070569, filed on Jul. 31, 2009, which is incorporated herein by reference in its entirety.

### BACKGROUND OF THE INVENTION

Exemplary embodiments of the present invention relate to a technology for fabricating a semiconductor device, and more particularly, to a semiconductor device capable of preventing the characteristic degradation caused by a Drain Induced Barrier Lowering (DIBL) effect, and a method for fabricating the same.

As the integration degree of semiconductor devices increases, channel lengths of the semiconductor devices have progressively decreased. When the channel lengths decrease, the DIBL effect may occur and thus the characteristics of the semiconductor devices may be degraded.

The DIBL effect refers to a phenomenon that a potential barrier decreases as a depletion region of a drain expands into a substrate, specifically, a channel region in a reverse bias state for a normal operation between the drain or source and a well.

The DIBL effect changes a threshold voltage of a semiconductor device, causing degradation in the operation characteristics of the semiconductor device. The degradation in the operation characteristics of the semiconductor device caused by the DIBL effect becomes significant as the channel length of the semiconductor device becomes shorter.

### SUMMARY OF THE INVENTION

Exemplary embodiments of the present invention are directed to a semiconductor device capable of preventing the characteristic degradation caused by a DIBL effect and a method for fabricating the same.

In accordance with an embodiment of the present invention, a semiconductor device includes: a gate formed over a substrate; a junction region formed in the substrate at both sides of the gate; and a depletion region expansion prevention layer surrounding sidewalls of the junction region in the substrate.

The depletion region expansion prevention layer may have a structure that surrounds at least lower part of the sidewalls of the junction region.

The depletion region expansion prevention layer may be a single layer formed of any one selected from the group consisting of an oxide layer, a nitride layer, and an oxynitride layer, or a multilayer in which the layers are stacked.

The semiconductor device may further include a gate spacer formed on sidewalls of the gate.

The junction region may include a first junction region under the gate spacer and a second junction region, a first junction region having a shallower junction depth and a lower impurity doping concentration than the second junction region.

The semiconductor device, may further include: a trench formed in the substrate at both sides of the gate; and a semiconductor layer filling the trench.

The depletion region expansion prevention layer may be positioned on the sidewalls of the trench and has a smaller height than the trench with respect to a bottom surface of the trench. The junction region may be formed in the semiconductor layer.

The semiconductor layer may be formed of the same material as the substrate.

The semiconductor layer may include an epitaxial layer.

In accordance with another embodiment of the present invention, a method for fabricating a semiconductor device includes: selectively etching a substrate to form a trench for a junction region; forming a depletion region expansion prevention region on sidewalls of the trench, the depletion region expansion prevention region having a smaller height than the trench; forming a semiconductor layer filling the trench; forming a gate over the substrate between the trenches; and forming the junction region by implanting impurity ions into the semiconductor layer.

The forming of the depletion region expansion prevention region may include: forming the depletion region expansion prevention layer along a surface of the substrate including the trench; performing a blanket etching process on the depletion region expansion prevention layer while leaving the depletion region expansion prevention layer on the sidewalls of the trench; filling the trench with a sacrifice layer; partially etching the depletion region expansion prevention layer using the sacrifice layer as an etching barrier so that the depletion region expansion prevention layer has the smaller height than the trench; and removing the sacrifice layer.

The depletion region expansion prevention layer may be a single layer formed of any one selected from the group consisting of an oxide layer, a nitride layer, and an oxynitride layer, or a multilayer in which the layers are stacked.

The forming of the junction region may include performing a primary ion implantation process on the semiconductor layer to form a first junction region; forming a gate spacer on sidewalls of the gate; and performing a secondary ion implantation process on the semiconductor layer to form a second junction region having a junction depth and a impurity doping concentration that are greater than the first junction region.

The semiconductor layer may be formed of the same material as the substrate.

The semiconductor layer may include an epitaxial layer.

### BRIEF DESCRIPTION OF THE DRAWINGS

FIGS. 1A and 1B are views illustrating a semiconductor device in accordance with an embodiment of the present invention.

FIGS. 2A to 2E are cross-sectional views illustrating a method for fabricating a semiconductor device in accordance with another embodiment of the present invention.

### DESCRIPTION OF SPECIFIC EMBODIMENTS

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

Exemplary embodiments of the present invention which will be described below provide a semiconductor device capable of preventing operation characteristics from being degraded by the DIBL effect and a method for fabricating the same. The semiconductor device includes a depletion region expansion prevention layer formed with such a structure that partially surrounds sidewalls of a junction region including a drain and a source. Therefore, a depletion region of the junction region which is formed in dependence upon the operation bias voltage is prevented from expanding detrimentally in a substrate, particularly, in the direction of a channel.

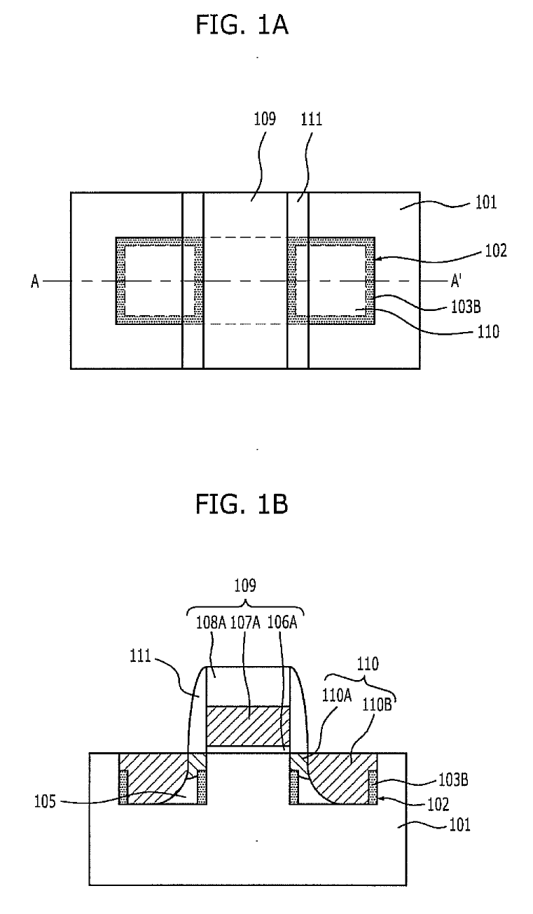

FIGS. 1A and 1B are views illustrating a semiconductor device in accordance with an embodiment of the present invention. FIG. 1A is a plan view of the semiconductor device, and FIG. 1B is a cross-sectional view taken along a line A-A′ of FIG. 1A.

Referring to FIGS. 1A and 1B, the semiconductor device in accordance with an embodiment of the present invention includes a gate 109 formed on a substrate 101, a junction region 110 formed in the substrate 101 at both sides of the gate 109, and a depletion region expansion prevention layer 103B partially surrounding sidewalls of the junction region 110 inside the substrate 101. At this time, the gate 109 may be a multilayer structure in which a gate insulating layer 106A, a gate electrode 107A, and a gate hard mask layer 108A are sequentially stacked.

The depletion region expansion prevention layer 103B serves to prevent/reduce a detrimental expansion of a depletion region in the substrate 101, particularly a channel region during an operation. That is, the depletion region expansion prevention layer 103B serves to prevent/reduce the occurrence of the DIBL effect. The depletion region expansion prevention layer 103B may be formed of an insulating layer. More specifically, the depletion region expansion prevention layer 103B may be a single layer formed of any one selected from the group consisting of an oxide layer, a nitride layer, and an oxynitride layer, or a multilayer in which the layers are stacked. For example, the depletion region expansion prevention layer 103B may be a silicon oxide layer (SiO₂), a silicon nitride layer (Si₃N₄), or a silicon oxynitride layer (SiON). Here, the channel region indicates a region corresponding to the surface of the substrate 101 under the gate 109 between the junction regions 110.

As shown in FIG. 1B, when the depletion region expansion prevention layer 103B has such a structure that surrounds at least lower part of the sidewalls of the junction region 110 (for example, excluding the sidewall adjacent to the surface of the substrate 101), an electrical path is still provided between the channel region and the junction region 110 during an operation.

The junction region 110 may be formed with a structure that has a uniform impurity doping concentration or a lightly doped drain (LDD) structure that includes first and second junction regions 110A and 110B having different impurity doping concentrations. At this time, the first junction region 110A adjacent to the gate 109 may have a shallower junction depth and a lower impurity doping concentration than the second junction region 110B.

The semiconductor device in accordance with the embodiment of the present invention may further include a trench 102 formed in the substrate 101 at both sides of the gate 109, a semiconductor layer 105 filling the trench 102, and a gate spacer 111 formed on both sidewalls of the gate 109.

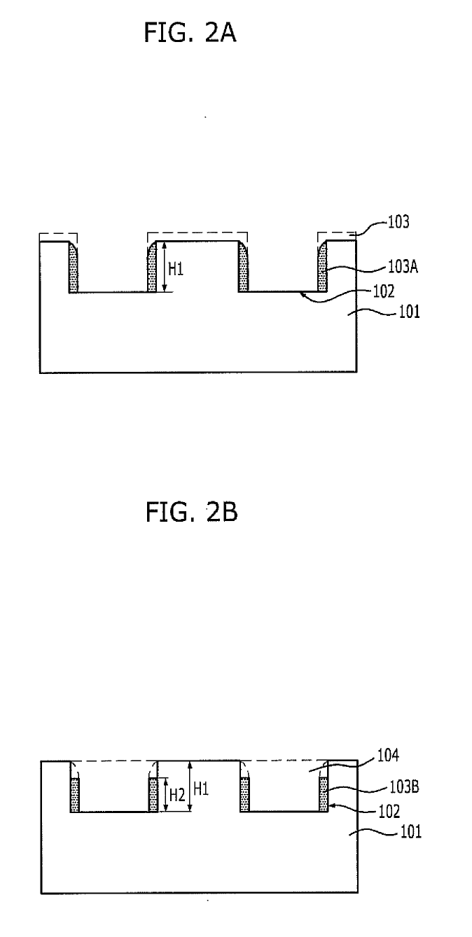

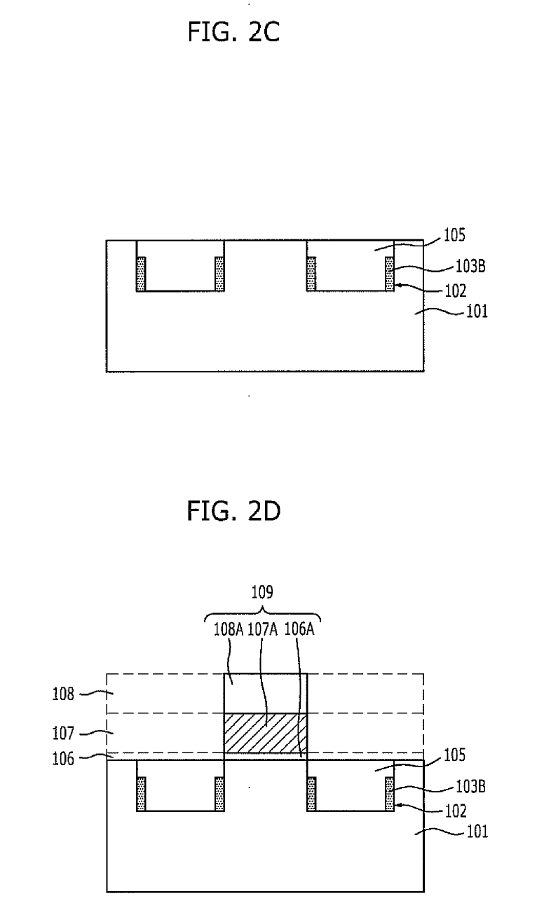

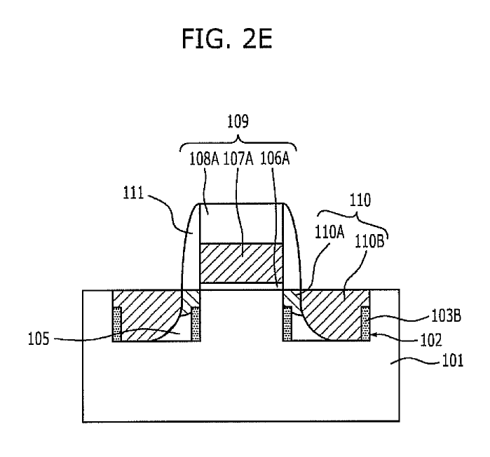

The trench 102 is provided to form the depletion region expansion prevention layer 103B which partially surrounds the sidewalls of the junction region 110 inside the substrate 101. The depletion expansion prevention layer 103B is positioned on sidewalls of the trench 102, and may have a lower height than the trench 102 (H1>H2, as shown in FIG. 2B), with a reference surface set to the bottom surface of the trench 102.

The semiconductor layer 105 filling the trench 102 may be formed of the same material as the substrate 101. Furthermore, the semiconductor layer 105 may be an epitaxial layer. For example, when a silicon substrate is used as the substrate 101, the semiconductor layer 105 may be a silicon epitaxial layer.

The junction region 110 may be positioned inside the semiconductor layer 105 such that the expansion of the depletion region in the junction region 110 during the operation is effectively prevented/reduced by the depletion region expansion prevention layer 103B positioned on the sidewalls of the trench 102.

The semiconductor device in accordance with the embodiment of the present invention includes the depletion region expansion prevention layer 103B partially surrounding the sidewalls of the junction region 110. Therefore, an expansion of the depletion region of the junction region 110 in the substrate 101, particularly in the direction of the channel during the operation, is prevented/reduced. As a result, although the channel length is reduced as the integration degree of the semiconductor device increases, the operation characteristics of the semiconductor device is prevented from being degraded by the DIBL effect.

FIGS. 2A to 2E are cross-sectional views illustrating a method for fabricating a semiconductor device in accordance with another embodiment of the present invention.

Referring to FIG. 2A, a substrate 101 is etched to form a trench 102. The substrate 101, for example, a silicon substrate, is etched by forming a photoresist pattern which has an opening corresponding to a junction region on the substrate 101 and using the photoresist pattern as an etching barrier. The photoresist pattern is not illustrated in FIG. 2A. At this time, the etching thickness or height H1 of the trench 102 may be adjusted in consideration of the junction depth of a junction region to be formed by a subsequent process.

A depletion region expansion prevention layer 103 is formed along the surface of the structure including the trench 102, and a blanket etching process, for example, an etch-back process is then performed in such a manner that the depletion region expansion prevention region 103 on the sidewalls of the trench 102 is formed in a spacer shape. Hereafter, reference numeral of the depletion region expansion prevention layer 103 remaining in a spacer shape on the sidewalls of the trench 102 is referred as 103A.

The depletion region expansion prevention layer 103A may be formed of an insulating layer. Specifically, the depletion region expansion prevention layer 103A may be a single layer formed of any one selected from the group consisting of an oxide layer, a nitride layer, and an oxynitride layer, or a multilayer in which the layers are stacked.

Referring to FIG. 2B, a sacrifice layer 104 filling the trench 102 is formed. The sacrifice layer 104 serves not only to prevent the depletion region prevention layer 103A from being etched more than desired during a subsequent etching process for adjusting the height of the depletion region expansion prevention layer 103A, but also to prevent the surface of the trench 102 from being damaged.

The sacrifice layer 104 may be formed of a polysilicon layer (poly Si). Furthermore, the sacrifice layer 104 may be formed through a series of processes in which the polysilicon layer is deposited on the entire surface of the surface 101 so as to sufficiently fill the trench 102 and planarization is then performed so that the surface of the substrate 101 is exposed. At this time, the planarization may be performed in such a manner that the top surface of the depletion region expansion prevention layer 103A is exposed. The planarization may be performed using a chemical mechanical polishing (CMP) method.

The exposed depletion region expansion prevention layer 103A is partially etched using the sacrifice layer 104 as an etching barrier such that the depletion region expansion prevention layer 103A has a height H2 lower than a height H1 of the trench 102, in reference to the bottom surface of the trench 102. Hereafter, the etched depletion region expansion prevention layer is denoted as 103B.

Here, the height H2 of the depletion region expansion prevention layer 103B is reduced to provide an electrical path between a channel region and a junction region which is to be formed inside the trench 102 through a subsequent process.

The sacrifice layer 104 is removed.

Referring to FIG. 2C, a semiconductor layer 105 filling the trench 102 is formed. The semiconductor layer 105, in which the junction region is to be formed through a subsequent process, may be formed of the same material as the substrate 101. Furthermore, the semiconductor layer 105 may be formed of an epitaxial layer. For example, when a silicon substrate is used as the substrate 101, the semiconductor layer 105 may be formed of a silicon epitaxial layer.

The semiconductor layer 105 may be formed through a series of processes in which an epitaxial layer is formed on the entire surface of the substrate 101 using an epitaxial growth method so as to sufficiently fill the trench 102 and planarization is performed so that the top surface of the substrate 101 is exposed. At this time, the planarization is performed using the CMP method.

Referring to FIG. 2D, a gate insulating layer 106, a gate conductive layer 107, and a gate hard mask layer 108 are sequentially formed on the entire surface of the substrate 101 including the semiconductor layer 105.

A photoresist pattern (not illustrated in FIG. 2D) is formed on the gate hard mask layer 108, and the gate hard mask layer 108, the gate conductive layer 107, and the gate insulating layer 106 are etched using the photoresist pattern as an etching barrier to form a gate 109. Hereafter, the etched gate hard mask layer, the etched gate conductive layer, and the etched gate insulating layer are denoted as 108A, 107A, and 106A, respectively.

Referring to FIG. 2E, impurity ions are implanted into the semiconductor layer 105 to form the junction region 110. At this time, the junction region 110 formed in the semiconductor layer 105 may have an LDD structure.

Specifically, impurity ions are primarily implanted into the semiconductor layer 105 to form a first junction layer 110A, and a gate spacer 111 is formed on both sidewalls of the gate 109. Then, impurity ions are secondarily implanted into the semiconductor layer 105 to form a second junction layer 110B having a larger junction depth and a higher impurity doping concentration than the first junction region 110A.

In an exemplary embodiment of the present invention, the depletion region expansion prevention layer 103B partially surrounding the sidewalls of the junction region 110 is formed through the above-described process. Therefore, an expansion of a depletion region of the junction region 110 in the substrate 101, particularly in the direction of the the channel during the operation, is prevented/reduced. As a result, although the channel length is reduced as the integration degree of the semiconductor device increases, the operation characteristics of the semiconductor device is prevented from being degraded by the DIBL effect.

In accordance with the embodiments of the present invention, the semiconductor device includes the depletion region expansion prevention layer partially surrounding the sidewalls of the junction region. Therefore, the semiconductor device prevents/reduces an expanding of the depletion region of the junction region in the substrate, particularly the channel region during the operation.

While the present invention has been described with respect to the specific embodiments, it will be apparent to those skilled in the art that various changes and modifications may be made without departing from the spirit and scope of the invention as defined in the following claims.

What is claimed is:

1. A semiconductor device, comprising:
a gate formed over a substrate;
a junction region formed in the substrate at both sides of the gate; and
a depletion region expansion prevention layer surrounding sidewalls of the junction region in the substrate.

2. The semiconductor device of claim 1, wherein the depletion region expansion prevention layer has a structure that surrounds at least lower part of the sidewalls of the junction region.

3. The semiconductor device of claim 1, wherein the depletion region expansion prevention layer is a single layer formed of any one selected from the group consisting of an oxide layer, a nitride layer, and an oxynitride layer, or a multilayer in which the layers are stacked.

4. The semiconductor device of claim 1, further comprising a gate spacer formed on sidewalls of the gate.

5. The semiconductor device of claim 4, wherein the junction region comprises a first junction region under the gate spacer and a second junction region, a first junction region having a shallower junction depth and a lower impurity doping concentration than the second junction region.

6. The semiconductor device of claim 1, further comprising:
a trench formed in the substrate at both sides of the gate; and
a semiconductor layer filling the trench.

7. The semiconductor device of claim 6, wherein the depletion region expansion prevention layer is positioned on the sidewalls of the trench and has a smaller height than the trench with respect to a bottom surface of the trench.

8. The semiconductor device of claim 6, wherein the junction region is formed in the semiconductor layer.

9. The semiconductor device of claim 6, wherein the semiconductor layer is formed of the same material as the substrate.

10. The semiconductor device of claim 6, wherein the semiconductor layer comprises an epitaxial layer.

11. A method for fabricating a semiconductor device, comprising:
selectively etching a substrate to form a trench for a junction region;
forming a depletion region expansion prevention region on sidewalls of the trench, the depletion region expansion prevention region having a smaller height than the trench;
forming a semiconductor layer filling the trench;
forming a gate over the substrate between the trenches; and
forming the junction region by implanting impurity ions into the semiconductor layer.

12. The method of claim 11, wherein the forming of the depletion region expansion prevention region comprises:
forming the depletion region expansion prevention layer along a surface of the substrate including the trench;
performing a blanket etching process on the depletion region expansion prevention layer while leaving the depletion region expansion prevention layer on the sidewalls of the trench;
filling the trench with a sacrifice layer;
partially etching the depletion region expansion prevention layer using the sacrifice layer as an etching barrier so that the depletion region expansion prevention layer has the smaller height than the trench; and
removing the sacrifice layer.

13. The method of claim 11, wherein the depletion region expansion prevention layer is a single layer formed of any one selected from the group consisting of an oxide layer, a nitride layer, and an oxynitride layer, or a multilayer in which the layers are stacked.

14. The method of claim 11, wherein the forming of the junction region comprises:
performing a primary ion implantation process on the semiconductor layer to form a first junction region;
forming a gate spacer on sidewalls of the gate; and
performing a secondary ion implantation process on the semiconductor layer to form a second junction region having a junction depth and a impurity doping concentration that are greater than the first junction region.

15. The method of claim 11, wherein the semiconductor layer is formed of the same material as the substrate.

16. The method of claim 11, wherein the semiconductor layer comprises an epitaxial layer.
